(19) United States
(12) Patent Application Publication
(10) Pub. No.: US 2026/0110736 A1
(43) Pub. Date: Apr. 23, 2026

(54) Protective device, protective assembly, electrical panel and associated test method

(71) Applicant: Schneider Electric Industries SAS, Rueil Malmaison (FR)

(72) Inventors: Guillaume TANGUY, Meylan (FR); Bruno BORDET, St. Martin le Vinoux (FR); Han WANG, Shanghai (CN)

(21) Appl. No.: 19/364,402

(22) Filed: Oct. 21, 2025

(30) Foreign Application Priority Data
Oct. 21, 2024 (FR) FR2411461

(51) Int. Cl. G01R 31/327; H01H 39/00; H01H 83/08; H01H 83/14; H02H 7/26

(52) U.S. Cl. CPC G01R 31/3274; H01H 39/006; H01H 83/08; H01H 83/14; H02H 7/268

(57) ABSTRACT

This protection device (300) comprises at least two conduction paths (303) and cut-off means (310) arranged on each of the conduction paths. The device comprises a microcontroller (320), which is configured to measure a differential current in the conduction paths with detection means (312), to evaluate a differential fault and to send a trip signal to the cut-off means when a differential fault of the first type is detected. The protection device (300) also includes a test loop (360), which is different from the detection means. The microcontroller (320) is configured to inject, into the conduction paths by means of the test loop, a first test signal representative of the electrical fault of the first type and, together with detection means, to measure the first test signal thus injected into the conduction paths.

### BACKGROUND

The present invention relates to an electrical protection device, a protection assembly comprising such an electrical protection device, and an electrical panel comprising such a protection device or such a protection assembly. The invention also relates to a method of testing such a protection device.

Electrical protection devices capable of detecting differential current faults, such as differential circuit breakers, are of interest here. There are several types of differential faults, which are defined in particular in the IEC 60755:2017 standard. In particular, the types of faults include the fact that the electrical signal is rectified, that the signal includes a high-frequency component, the rating—for example 30 mA or 300 mA—etc. Differential circuit breakers are generally configured to detect a specific type of differential fault. During manufacture, the protection devices are tested, in the factory, by injecting, into the conduction paths, a test signal representative of the type of fault considered, so as to check the correct operation of the differential circuit breaker.

Once the protection device is installed in an electrical installation, for example in an electrical panel, to check that the circuit breaker is operating satisfactorily, differential circuit breakers are generally equipped with a test button, which allows a representative current to be injected into conduction paths of the circuit breaker, so as to voluntarily trip the circuit breaker. In other words, it is checked that the detection—tripping chain is operational, but it is no longer possible to test the circuit breaker with a test signal which corresponds exactly to the type of fault considered.

It is these problems that the invention more particularly intends to remedy, by proposing a protection device which allows a more precise test of the differential faults.

### SUMMARY

To this end, the invention relates to an electrical protection device, which is configured to connect a power source to an electrical load, the protection device comprising:
at least two conduction paths, including a first path, which is configured to be connected to a phase of the power source, and a second path, which is configured to be connected either to another phase of the power source, or to a neutral of the power source, each conduction path comprising:
   an incoming terminal, which is configured to be connected to a phase or possibly to the neutral of the power source,
   an outgoing terminal, which is associated with the incoming terminal and which is configured to be connected to a terminal of the electrical load, and
   cut-off means, which are configured to switch between an armed configuration, in which each incoming terminal is electrically connected to the associated outgoing terminal, and a tripped configuration, in which each incoming terminal is electrically isolated from the associated outgoing terminal,
detection means, which include measurement loops configured to measure a current flowing through each conduction path,
a microcontroller, which is configured to:
   evaluate the differential-current measurement of the detection means with the help of a first detection filter, the first detection filter being previously stored in a memory of the microcontroller and being designed to detect a differential fault of a first type, and
   when a differential fault of the first type is detected, send a trip signal to the cut-off means, so as to cause the cut-off means to switch from the armed configuration to the tripped configuration,
      wherein:
the protection device comprises a test loop, which is different from the measurement loop and which is configured to inject an electrical signal into the conduction paths,
the microcontroller is configured:
   to inject a first test signal into the conduction paths by means of the test loop, the first test signal being an electrical signal representative of the electrical fault of the first type and, at the same time,
   to measure, by means of the measurement loop, the first test signal injected into the conduction paths by means of the test loop.

By virtue of the invention, the differential tripping tests are carried out with test signals which satisfy exactly the same criteria of the detection filters. It is thus possible to check the correct operation of the detection chain completely, including the measurement, the analysis of the measurements, and the tripping of the cut-off means. In addition, the detection chain, via which the measurement is made, is different from the test chain, via which the test signal is injected into the conduction circuit. The reliability of the measurement and of the device is thus ensured.

According to advantageous but non-mandatory aspects of the invention, such a protection device may incorporate one or more of the following features, either alone or in any technically permissible combination:
the microcontroller comprises a digital-to-analogue converter, an analogue output of the digital-to-analogue converter being connected to the test loop, while each test signal is stored in the form of a digital test signal in the memory of the microcontroller, and each test signal in digital form is transformed, by the digital-to-analogue converter, into an analogue signal of the test loop, the analogue signal of the test loop being the first test signal.
The microcontroller is configured to detect differential faults of a plurality of different types, the plurality of types including the first type, while a respective detection filter corresponds to each differential fault type, the detection filter associated with each differential fault type being previously stored in the memory of the microcontroller, and the protection device comprises communication means, which are configured to receive configuration information from a device that is remote from the protection device, so as to specify the one or more types of differential faults for which, in the event that the corresponding differential fault is detected, the microcontroller sends the trip signal to the cut-off means.
The plurality of differential fault types include at least one differential fault type defined by the IEC 60755:2017 standard.
A respective test signal corresponds to each differential fault type, the test signal associated with each differential fault type being previously stored in the memory of the microcontroller, while, for each differential fault type considered amongst the plurality of differential fault types, the microcontroller is configured to inject, into the conduction paths, a corresponding test signal, the corresponding test signal being an electrical signal representative of the electrical fault of the type considered.
The protection device comprises, in addition to the incoming and outgoing terminals, transfer terminals, which are intended to be connected to a transfer bus, the transfer bus being different from the power bus, so as to supply the microcontroller with electrical energy independently of the armed or tripped configuration of the switching mechanism.
The communication means are configured to receive the configuration information via the transfer terminals and the transfer bus.

The invention also relates to a distribution assembly, which comprises:
a copy of the protection device as defined above,
a distribution device with a power bus,
   wherein the protection device is mounted on the distribution device in a reversible manner, the incoming terminals being electrically connected to the power bus.

The invention also relates to an electrical panel, which comprises:
an enclosure having a bottom,
the protection device as defined above, or the distribution assembly as defined above,
   wherein the protection device or the distribution assembly is fixed to the bottom of the enclosure.

According to another aspect, the invention relates to a method of testing an electrical protection device as defined above, the test method including:
injecting, into the conduction paths and using the test loop, a first test signal representative of a differential fault of a first predetermined type, characteristics of the differential fault of the first type being previously stored in a memory of the microcontroller,
during the injection of the first test signal, measuring, in the conduction paths and using the measurement loop, a differential current between the conduction paths,
comparing the differential current measurement with a first detection filter that is characteristic of the differential fault of the same type as the first test signal, the first detection filter being previously stored in a memory of the microcontroller, then
as a result of the comparison, determining a differential fault corresponding to the differential fault type considered, then, if the result of the determination is positive, sending, via the microcontroller, a trip signal for the cut-off means.

This test method leads to the same advantages as those mentioned above with respect to the protection device of the invention.

Advantageously, the test method includes:
prior to injecting the first test signal into the conduction paths, receiving configuration information, with the help of the transmission means, so as to specify a differential fault type amongst a plurality of differential fault types previously stored in the memory of the microcontroller, for which, in the event that the corresponding differential fault is detected, the microcontroller sends the trip signal to the cut-off means,
then, when the first test signal is being injected into the conduction paths, the first test signal corresponds to the differential fault type specified by the configuration information,
then, when the differential current measurement is being compared, the detection filter corresponds to the differential fault type specified.

### BRIEF DESCRIPTION OF THE DRAWINGS

The invention will be better understood and other advantages thereof will become more clearly apparent in light of the following description of one embodiment of a protection device, of a distribution assembly, of an electrical panel and of a test method, according to the principle thereof, provided solely by way of example and given with reference to the appended drawings, in which:

FIG. 1 is a partially exploded perspective view of an electrical panel according to the invention, the electrical panel comprising a distribution assembly with at least one protection device, themselves also according to the invention;

FIG. 2 is a partially exploded perspective view of the distribution assembly of FIG. 1;

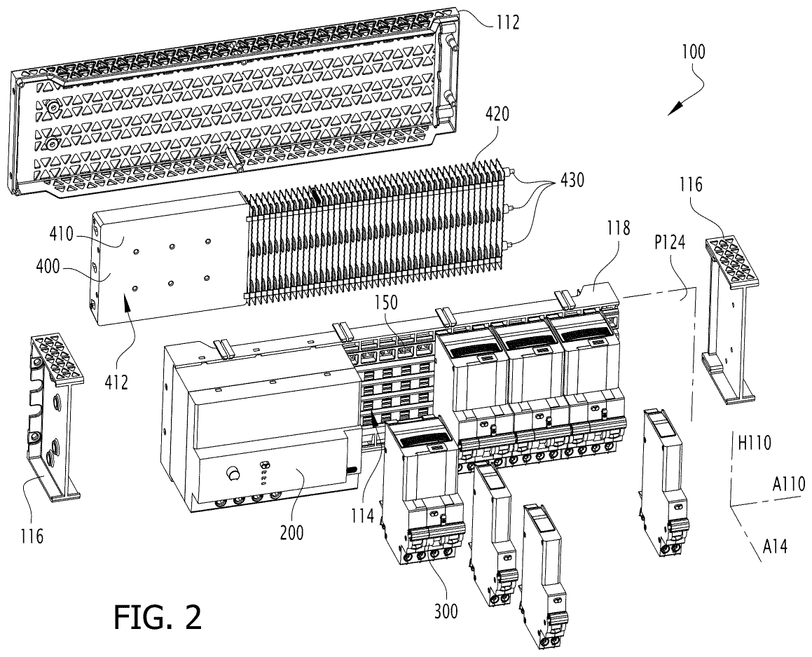

FIG. 3 respectively shows, on two inserts a) and b), a perspective view of the distribution assembly of FIG. 1, some parts being hidden, and a perspective view of a transfer bus of the distribution assembly;

FIG. 4 is a partially exploded perspective view of the distribution assembly of FIG. 1, some parts being hidden;

FIG. 5 is a schematic representation of the distribution assembly of FIG. 1, and

FIG. 6 is a diagram illustrating a method of testing the protection device of FIG. 1.

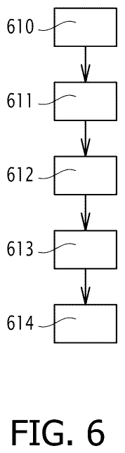

### DETAILED DESCRIPTION

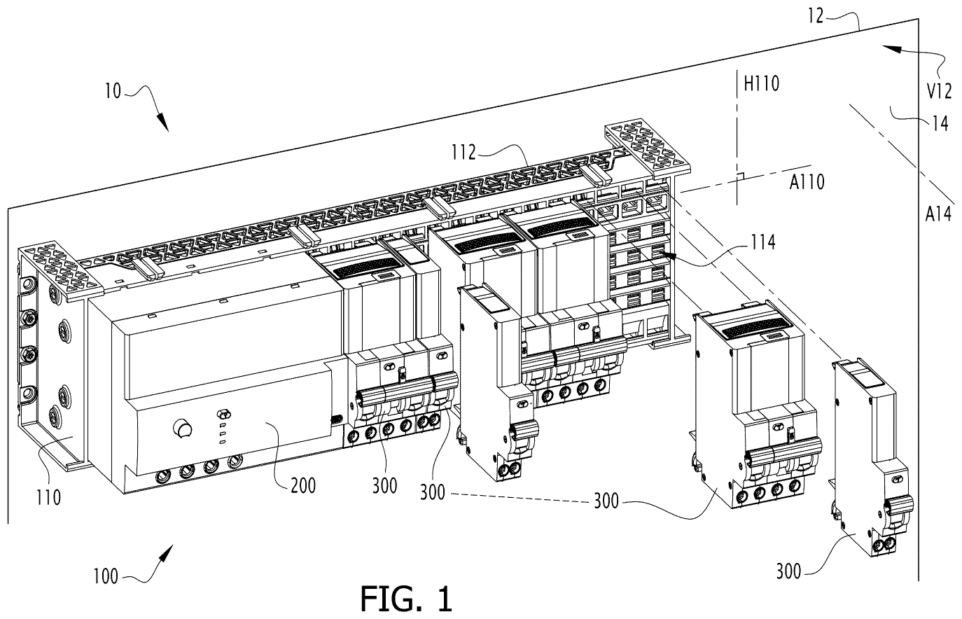

An electrical panel 10, according to the invention, is shown in FIG. 1. The electrical panel 10 comprises a box 12, which delimits an enclosure V12 and has a bottom 14. The bottom 14 is generally in a plane orthogonal to a depth axis A14. The enclosure V12 is advantageously closed by a door, which is not shown.

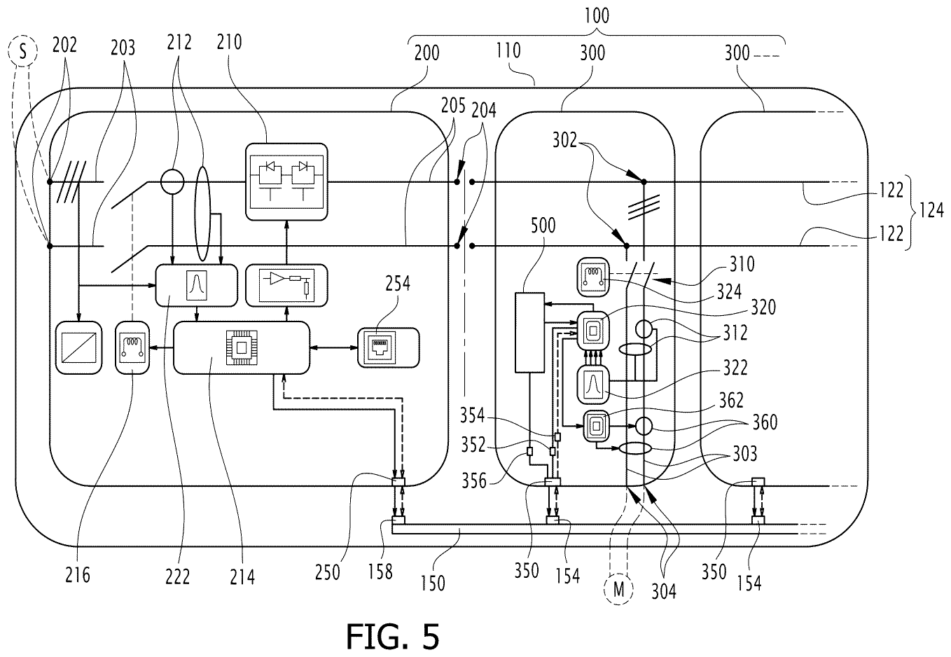

The electrical panel 10 comprises a distribution assembly 100. The distribution assembly 100 is fixed to the bottom 14 of the housing 12. 1. The distribution assembly 100 is configured to distribute electrical energy from a power source S to at least one electrical load M, for example a motor. The power source S and the electrical load M, which are shown schematically in FIG. 5, do not form part of the invention but are used to explain the operating context thereof. The power source S comprises a neutral and at least one phase. In the example illustrated, the power source S is a three-phase source, comprising a neutral and three phases. In a variant that is not illustrated, the power source S is single-phase, comprising a neutral and a single phase. According to another variant, the power source comprises three phases, and no neutral.

The distribution assembly 100 advantageously comprises a distribution device 110, by means of which the distribution assembly 100 is fixed to the bottom 14, a main housing 200, which is assembled to the distribution device 110, preferably in a reversible manner, and at least one protection device 300, here seven protection devices, each protection device 300 being assembled to the distribution device 110 in a reversible manner, in a mounted position of the protection device 300. The protection devices 300 here are outgoing housings, the principles of the invention being of course transposable to protection devices of a different type. It is thus possible to replace, if necessary, the main housing 200 in the event of a malfunction of the main housing 200, while retaining the other elements of the distribution assembly 100, distribution device 110 and outgoing housing(s) 300, this being economical. Similarly, it is possible to replace, if necessary, one or more of the protection devices 300, for example in the event of a malfunction, while retaining the other elements, distribution device 110 and main housing 200, this being economical.

The distribution device 110 has an elongate shape, which extends along a main axis A110. When the distribution assembly 100 is in a normal operating configuration, the main axis A110 is parallel to the bottom 14, in other words orthogonal to the depth axis A14. Preferably, the main axis A110 is horizontal, as illustrated in FIG. 1. A height axis H110 is defined as an axis orthogonal both to the depth axis A14 and to the main axis A110. The description is given with reference to the orientation of the various elements as shown in the figures, in the knowledge that this may be different in reality.

In the example of FIG. 1, the main housing 200 is located on the left of the distribution assembly 100, the protection devices 300 being located on the right of the main housing 200.

When the distribution assembly 100 is fixed to the bottom 14, a rear portion 112 of the distribution device 110 is oriented facing the bottom 14, in other words oriented towards a rear direction of the distribution assembly 100. The rear direction is thus parallel to the depth axis A14. A front direction is also defined as being a direction opposite to the rear direction.

The distribution device 110 thus has a mounting face 114, which is generally oriented towards the front and is provided for mounting the main housing 200 and each protection device 300.

The rear portion 112 is made of an electrically insulating material, for example a synthetic polymer. The rear portion 112 here has a generally rectangular shape, which extends in its largest dimension parallel to the main axis A110. The small sides of the rectangle are thus parallel to the height axis H110. The distribution device 110 here comprises two flanges 116, which are made of an electrically insulating material. The two flanges 116 are assembled to the small sides of the rear portion 112 so as to form a basket.

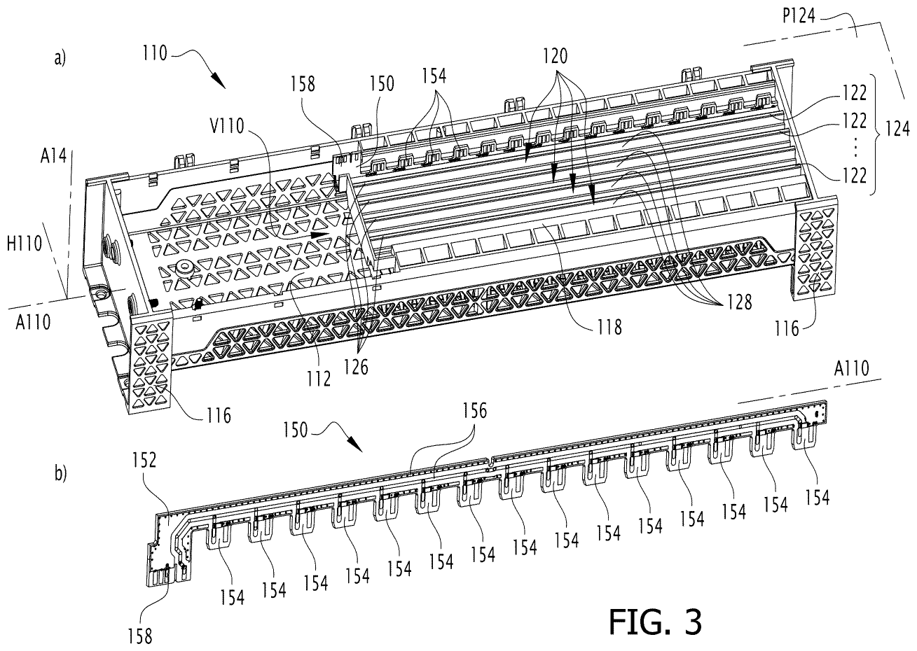

The distribution device 110 here comprises an insulating wall 118, which is made of an electrically insulating material and is assembled to the rear portion 112 and to the flanges 116, so as to form a cavity V110, as illustrated in FIG. 3.

In the example illustrated, the distribution device 110 advantageously comprises a cooling device 400, which is received in the cavity V110 and is provided to remove part of the heat generated by the main housing 200 when the distribution assembly 100 is in operation. The cooling device 400 is thus located on a rear side of the insulating wall 118, while on a front side of the insulating wall 118, the front side being oriented opposite to the rear side, the insulating wall 118 encompasses grooves 120 provided to receive a plurality of busbars 122, here four busbars 122. The busbars 122 together form a power bus 124 of the distribution device 110 and, by extension, of the distribution assembly 100. The distribution device 110 is thus a power distribution device.

The busbars 122 extend parallel to each other along the main axis A110 of the distribution assembly 100 and are aligned along the height axis H110. The busbars 122 together define a connection plane P124, which is a plane orthogonal to the depth axis A14, in other words parallel to the height axis H110 and to the main axis A110. The mounting face 114 is generally parallel to the connection plane P124.

The cooling device 400 comprises a contact plate 410, which is provided to capture part of the heat released by the main housing 200, a radiator 420, which is provided to dissipate the heat into the ambient air, and at least one heat pipe 430, here three heat pipes, which connects the contact plate 410 to the radiator 420 and is configured to transfer part of the heat captured by the contact plate 410 to the radiator 420.

The contact plate 410 here has a parallelepiped shape and has a contact face 412, which extends parallel to the connection plane P124. The contact face 412 is configured to cooperate, in particular via complementarity of shapes, with a rear face 230 of the main housing 200 in the configuration mounted on the distribution device 110, so as to promote heat transfer between the contact plate 410 and the main housing 200.

The busbars 122 include at least one phase bar and, possibly, a neutral bar, the neutral bar being associated with the neutral of the power source S, each phase bar being associated with a respective phase of the power source S. In the example illustrated, the power bus 124 comprises four busbars 122, the power source S being a three-phase source with a neutral. The distribution assembly 100 here has a so-called “3P+N”, or simply 3PN, configuration.

In a variant that is not shown, the power source S is three-phase, with or without neutral, while the distribution assembly does not comprise a busbar associated with the neutral. In other words, the power bus 124—and by extension the distribution assembly 110—comprises only three phase bars, each associated with a respective phase of the power source S. The distribution assembly is then in a so-called 3P configuration. More generally, the power bus 124 is configured to be connected to the power source S.

The principles of the invention are transposable regardless of the number of phases of the power source S. According to another variant that is not illustrated, the power source S is single-phase, that is to say comprises only the neutral and a single phase. The busbars then include a single phase bar and the neutral bar. The distribution assembly is then in a so-called P+N, or simply PN, configuration. Regardless of the configurations, there are always a plurality of busbars, which include at least one phase bar, and possibly a neutral bar.

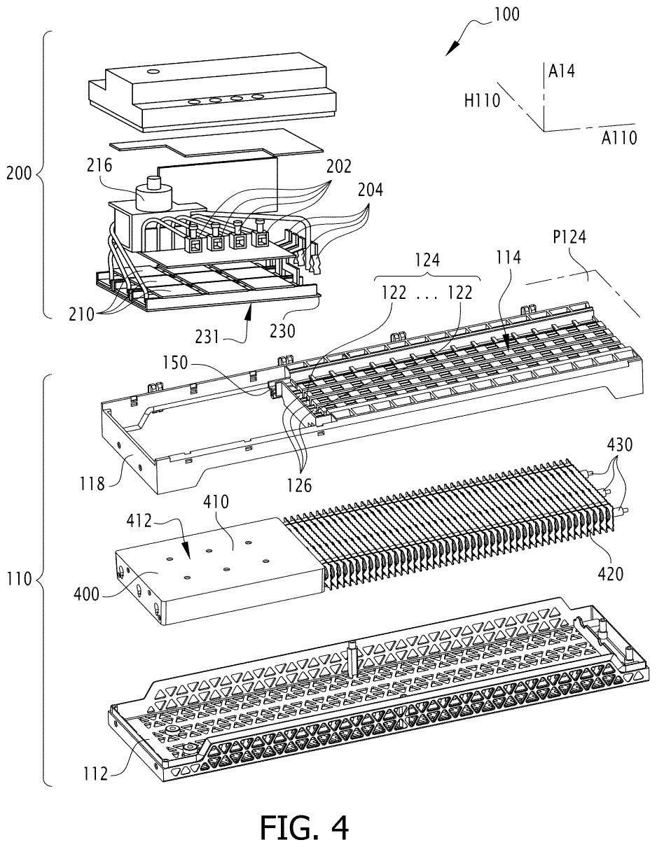

The main housing 200 will now be described, in particular with reference to FIGS. 4 and 5. In FIG. 5, the circuit of a single phase is shown, the three phases being shown, according to a known convention, by three parallel lines across the circuit.

The main housing 200 comprises incoming terminals 202, which are configured to be connected to the neutral and to each phase of the power source S, and outgoing terminals 204, which are configured to be connected to the busbars, each outgoing terminal being associated with a respective busbar and with a respective incoming terminal. The incoming terminals 202 here are screw terminals. Advantageously, the outgoing terminals 204 are connection clamps, which are each provided for reversible connection to a respective busbar 122, according to a connection movement oriented towards the rear of the distribution assembly 100. Thus, during the connection movement of the outgoing terminals 204 to the busbars 122, the rear face of the main housing 200 comes to bear against the contact face 412.

For each incoming terminal 202, the main housing comprises a corresponding incoming line 203, which is connected to the corresponding incoming terminal 202, and an outgoing line 205, which is connected to the associated outgoing terminal 204.

The main housing 200 comprises main cut-off means 210, which are switchable between a conductive configuration, in which each incoming terminal 202 associated with a phase of the power source S is electrically connected to the associated outgoing terminal 204, the main housing 200 being in a conductive configuration, and a cut-off configuration, in which the passage of an electric current between the incoming terminal 202 and the associated outgoing terminal 204 is prevented, the main housing 200 being in a cut-off configuration.

In the preferred example illustrated, the main cut-off means 210 are static cut-off means, that is to say power switches based on semiconductor components, preferably insulated-gate field-effect transistors, called JFETs or MOSFETs, and are thus referred to as “static” as opposed to cut-off means with a moving contact. The static cut-off means 210 are connected in series between the incoming line 203 and the associated outgoing line 205. The static cut-off means 210 are shown schematically in FIGS. 4 and 5. In a variant that is not shown, the main cut-off means 210 are electromechanical cut-off means with separable contacts.

During operation, the cut-off means 210 release heat, of the order of a few tens of Watts. The cut-off means 210 are advantageously disposed so as to promote the transfer of at least part of the released heat to the cooling device 400.

In particular, the cut-off means 210 are advantageously arranged against a rear wall 231 of the main housing 200, preferably in surface contact against the rear wall 231. The rear wall 231 is for example present when the main housing 200 is removable from the contact plate 410. The rear wall 231 encompasses the rear face 230, the rear face 230 being oriented opposite the cut-off means 210. The rear wall 231 is thus interposed between the cut-off means 210 and the contact plate 410 when the main housing 200 is mounted on the distribution device 110, such that part of the heat generated by the cut-off means 210 during operation is transferred to the contact plate 410 through the rear wall.

The rear wall 231 is made of a thermally conductive and electrically insulating material. In the example illustrated, the rear wall 231 is formed of an assembly of an electrically insulating insulating element 232, made of synthetic polymer material, and of a copper plate 233, which provides rigidity to the assembly while promoting thermal conductivity, the copper plate 233 encompassing the rear face 230 and bearing against the contact plate 410 when the main housing 200 is mounted on the distribution device 110. In a variant that is not illustrated, the copper plate 233 is omitted; the rear face 230 is thus formed directly by the insulating element 232.

The main housing 200 comprises main detection means 212, which are configured to measure electrical quantities across the outgoing terminals and to detect an electrical fault on the basis of the measured values. The main detection means 212 are shown schematically here by measurement loops, which are arranged here on the outgoing lines 205. The schematic representation of the main detection means does not limit the type of electrical faults that the main detection means 212 are capable of detecting.

The main housing 200 is configured to transition from the conductive configuration to the cut-off configuration when the main detection means 212 detect a first electrical fault, for example a differential fault or a short-circuit fault.

The main housing 200 comprises a control unit 214, or ECU standing for Electronic Control Unit, which is configured to control the static cut-off means 210, in other words to cause the static cut-off means 210 to switch between the conductive configuration and the cut-off configuration. The control unit 214 is also configured to analyse the values measured by the main detection means 212 and to determine, on the basis of predefined criteria corresponding to a predetermined type of electrical fault, the presence of an electrical fault of the predetermined type. In FIG. 5, the use of predefined criteria is shown schematically by the presence of a so-called “primary” filter 222, the primary filter 222 being interposed between the main detection means 212 and the control unit 214.

Thus, the main detection means 212 are configured to detect electrical faults of short-circuit type. For example, the main detection means 212 include current sensors, in particular one current sensor per phase, while the control unit 214 is configured to analyse the measurements made by the current sensors and to detect a short circuit.

Preferably, the main detection means 212 also include a differential-current detection device. There are several types of differential faults, which are defined in particular in the IEC 60755:2017 standard. In particular, the types of electrical faults include the fact that the electrical signal is rectified, that the signal includes a high-frequency component, the rating—for example 30 mA or 300 mA—, etc. It is understood that the primary filter 222 defines criteria for detection of electrical faults by the control unit 214 of the main housing 200. Preferably, the primary filter 222 defines criteria for detecting a type of predetermined differential fault, the predetermined differential fault being chosen from amongst the faults defined in the IEC 60755:2017 standard.

Preferably, the main housing 202 also comprises, for each incoming terminal 202, a general cut-off device 216, which is a cut-off device with separable contacts, here a disconnector. The general cut-off device 216 is controlled by the electronic control unit 214 and allows the power source S to be electrically disconnected from the distribution assembly 100, for example in the event of a malfunction of the static cut-off means 210. The general cut-off device 216 is interposed between each incoming terminal 202 and the static cut-off means 210.

Advantageously, the distribution device 110, and by extension the distribution assembly 100, also comprises a transfer bus 150. The transfer bus 150, which is shown in isolation in FIG. 3b), is provided for operation to supply energy to each protection device 300 in the mounted position, that is to say connected to the busbars 122. The transfer bus 150 here is therefore an energy transfer bus, in other words a power supply bus, which is separate from the power bus 124. According to one illustrative example, the transfer bus 150 operates at a voltage of a few tens of volts, for example 50 V DC, while the power bus 124 operates at a voltage of 400 V three-phase AC. The transfer bus 150 here is a separate part, which is assembled to the remainder of the distribution device 110.

The transfer bus 150 comprises a body 152, which is made of an electrically insulating material, which has an elongate shape extending along the power bus 124. Thus, the transfer bus 150 extends along the main axis A110.

The transfer bus 150 defines a plurality of mounting areas 154, which are provided to be connected to each protection device in the mounted position, the mounting areas 154 being distributed, preferably regularly, along the main axis A110 and each being associated with a unique position along the main axis A110. The transfer bus 150 preferentially comprises fifteen mounting areas 154, which are spaced apart from each other by a pitch of 18 mm here. Other pitches are of course possible. In a variant that is not shown, the mounting areas 154 are spaced apart from each other by a pitch of 9 mm.

The transfer bus 150 comprises at least two transfer lines 156, which extend along the body 152 and are configured to be electrically connected to each protection device 300 in the mounted position. The transfer lines 156 therefore comprise power supply lines.

The transfer bus 150 also comprises a connection area 158, which is provided for the connection of the main housing 200 in the mounted position on the distribution device 110. For example, the main housing 200 comprises a complementary terminal block 250, which is configured to cooperate with the connection area 158, such that the main housing is electrically connected to the transfer lines 156. In the preferred example illustrated, the main housing 200 draws the electrical energy necessary to supply power to the transfer bus 150 on the neutral and the phases of the power source S, between the static cut-off means 210 and the general cut-off device 216, the electrical energy thus supplied being available to the protection devices 300 for their operation, as described below.

The transfer bus 150 here is realized by a printed circuit board, the transfer lines 156 being conductive tracks formed on the surface of the board, while the mounting areas 154 and the connection area 158 are tabs formed in the substrate of the board. In the example illustrated, the transfer bus 150 advantageously integrates a communication bus between the main housing 200 and each protection device 300.

The protection devices 300 will now be described.

Each protection device 300 thus comprises an incoming terminal block which is reversibly connectable to the busbars 122 and which comprises at least two incoming terminals 302, each incoming terminal 302 being configured to be electrically connected to a respective busbar 122. For each protection device 300, the incoming terminals 302 include a neutral incoming terminal, which is configured to be electrically connected to the neutral bar, and between one and three other incoming terminals, which are each configured to be connected to a respective phase bar. Each protection device 300 is configured to be reversibly mounted on the power bus 114, such that each incoming terminal 302 is electrically connected to the corresponding busbar 122.

Each protection device 300 also comprises an outgoing terminal block, which is configured to be connected to a respective electrical load M and which comprises outgoing terminals 304, each outgoing terminal 304 being respectively associated with a respective incoming terminal 302 and being connected to this incoming terminal 302 via a conduction path 303. The outgoing terminals 304 are shown schematically in FIG. 5.

In the non-limiting example illustrated, the protection devices 300 have different widths, the width being measured along the main axis A110. Thus, the protection devices 300 here are divided into two sub-groups, which correspond to two different widths, with thin protection devices 300 and wide protection devices 300, which are substantially three times wider than the thin protection devices 300. Other widths of protection devices 300 are of course conceivable. The width of the protection devices 300 is preferably a multiple of the pitch between each mounting area 154 of the transfer bus 150, i.e. 18 mm here. In a variant that is not shown, the protection devices 300 have a width equal to a multiple of 9 mm.

In the example illustrated, a protection device 300 configured to supply power to a single-phase electrical load advantageously has a width of 18 mm, while a protection device 300 configured to supply power to a three-phase electrical load has a width of three times 18 mm, i.e. 54 mm.

The thinnest protection devices 300 are configured to be connected to two busbars 122, including a neutral bar and a phase bar, while the widest protection devices 300 are configured to be connected to four busbars 122. The principles of the invention are applicable regardless of the number of phases to which each of the protection devices 300 is connected.

Preferably, the distribution device 110 is provided to receive five protection devices 300, which each comprise four incoming terminals, in other words five wide protection devices 300. According to an example that is not illustrated, the distribution assembly 100 comprises five protection devices 300, which each comprise four incoming terminals 302. As a corollary, the distribution device 110 is also provided to receive fifteen thin protection devices 300 each comprising two incoming terminals 302.

The busbars 122 each comprise:
a power supply portion 126, which is configured to be connected to an associated outgoing terminal 204 of the main housing 200 in a mounted configuration of the main housing, and
a connection portion 128, which extends on the same side of the power supply portion 126. The connection portions 128 are geometrically located on a front side of the connection plane P124 and together define a connection area of the power bus 124.

In FIG. 4, only the power supply portions 126 of the busbars 122 are visible, the connection portions 128 being hidden. The connection area is configured to receive at least one protection device 300, such that the protection device is connected to the power bus 129. The protection device 300 is then able to be connected to an electrical load, so as to supply electrical power to the electrical load.

Each protection device 300 comprises cut-off means 310, which are interposed between each incoming terminal 302 and the corresponding outgoing terminal 304. The cut-off means 310 are configured to switch between an armed configuration, in which each incoming terminal is electrically connected to the associated outgoing terminal, and a tripped configuration, in which the incoming terminal is electrically isolated from the associated outgoing terminal. The cut-off means 310 here are formed by an electromechanical mechanism with separable contacts. The armed configuration of the cut-off means 310 here therefore corresponds to a closed position of the moving contacts, the protection device 300 in question being in a closed configuration, while the tripped configuration of the cut-off means 310 corresponds to an open position of the separable contacts, the protection device 300 in question being in an open configuration. In a variant that is not shown, the cut-off means 310 of the protection device 300 are static cut-off means.

Each protection device 300 comprises secondary detection means 312, which are configured to measure electrical quantities across the corresponding outgoing terminals and to detect at least one electrical fault of a predetermined type, that is to say corresponding to predetermined detection criteria. In particular, the secondary detection means 312 are configured to measure an electric current flowing through each conduction path 303. The secondary detection means 312 are shown schematically here by measurement loops, which are arranged on the conduction paths 303 connecting the incoming terminals 302 to the outgoing terminals 304 here. The schematic representation of the secondary detection means 312 does not limit the type of electrical faults that the secondary detection means are capable of detecting. Thus, the secondary detection means 312 are configured to detect electrical faults of differential type and, optionally, of short-circuit type.

For example, the secondary detection means 312 include current sensors, in particular one current sensor per phase, while the protection device 300 comprises a microcontroller 320, which receives the measurements from the current sensors and is capable of determining whether the one or more measured currents exceed a short-circuit threshold.

The microcontroller 320 is supplied with power via the transfer bus 150. To this end, each protection device 300 comprises a transfer terminal block 350, which comprises transfer terminals - not shown -, the transfer terminal block 350 being configured to be connected to the transfer bus 150 such that each transfer terminal is electrically connected to a respective transfer line 156. The transfer terminal block 350 here is therefore a power supply terminal block. The transfer terminals are different from the incoming terminals 302 or the outgoing terminals 304. The protection device 300 advantageously comprises a first power supply unit 352, also abbreviated to PSU, which is configured to receive electrical energy from the transfer bus 150, in particular from transfer lines 156 dedicated to supplying operating energy, and to supply operating electrical energy to the microcontroller 320. By extension, the first power supply unit 352 is also configured to supply operating energy to the secondary detection means 312.

Advantageously, the transfer bus 150 is also used to transfer data between each microcontroller 320 and the control unit 214 of the main housing 200. For example, the transfer of information passes through the same transfer lines 156 used for the transfer of energy. As an alternative that is not shown, the transfer bus 150 comprises specific information transfer lines, different from the transfer lines 156 being used for the power supply. The information transfer lines are preferentially formed on the transfer bus 150.

The protection device 300 advantageously comprises communication means 354, which are configured to receive information coming from a device that is remote from the protection device 300. In the example illustrated, the communication means 354 are separate from the microcontroller 320. In a variant that is not illustrated, the communication means 354 are integrated into the microcontroller 320.

The communication means 354 are advantageously configured to receive information via the transfer terminals 350 and the transfer bus 150. In the preferred example illustrated, the protection device 300 is configured to receive information coming from the main housing 200, which constitutes a first example of a remote device. In the example illustrated, the main housing 200 comprises main communication means 254, which are represented here by a socket in the RJ45 format and which are provided so that a user is able to configure the main housing 200 and, more generally, the distribution assembly 100. According to one advantageous example of use, for each type of electrical load connected to the outgoing terminals 304, the configuration of the protection device 300 is adapted accordingly, so as to offer the most suitable protection against differential faults.

In a variant that is not illustrated, the communication means 354 of the protection device 300 comprise a connection socket, for example a socket in the RJ45 format, for receiving information. In this case, the information does not pass via the transfer bus 150. According to another variant that is not illustrated, the communication means 354 of the protection device 300 and/or the main communication means 254 of the main housing 200 are wireless means.

In the example illustrated, the protection device 300 advantageously comprises a supervision circuit 500 and a second power supply unit 356. The supervision circuit 500 is provided to supervise the correct operation of the microcontroller 320. The second power supply unit 356 is different from the first power supply unit 352 and is provided to receive electrical energy from the transfer bus 150 and to supply operating energy to the supervision circuit 500. These aspects are not described in greater detail in the context of the present description.

The secondary detection means 312 include a differential current detection device, for example a measurement loop, configured to measure a differential current. The microcontroller 320 is thus configured to evaluate the differential current measurement using a detection filter 322, the detection filter 322 being previously stored in a memory of the microcontroller 320 of the protection device 300 and being adapted for the detection of a differential fault of a first type.

It is understood that the secondary filter 322 defines the criteria for detecting electrical faults detected by the microcontroller 320 of the protection device 300. A specific secondary filter 322 therefore corresponds to each type of electrical fault given. Preferably, the secondary filter 322 defines criteria for detecting a predetermined differential fault type, which is chosen from amongst the faults defined in the IEC 60755:2017 standard.

Each microcontroller 320 is supplied with electrical operating energy via the transfer bus 150, independently of the configuration, armed or tripped, of the cut-off means 310.

Each protection device 300 here comprises an actuator 324, which is configured to move the electromechanical cut-off means 310 into the open position when the actuator 324 receives a trip signal, the microcontroller 320 being configured to send the trip signal to the actuator 324 when an electrical fault is detected, in particular a short-circuit fault or a differential fault. More generally, each protection device 300 is configured to transition from the closed configuration to the open configuration when the secondary detection means 312—and by extension the microcontroller 320—detect an electrical fault.

According to one aspect of the invention, the protection device 300 comprises a test loop 360, which is different from the measurement loop of the secondary detection means 312 and which is provided to inject an electrical signal into the conduction paths 303. In the example illustrated, the microcontroller 320 is configured to inject, by means of the test loop 360, a first test signal into the conduction paths 303, the first test signal being an electrical signal representative of the electrical fault of the first type. At the same time, the microcontroller 320 is configured to measure, by means of the measurement loop 312, the first test signal injected into the conduction paths 303 by means of the test loop 360.

Thus, it is possible to inject into the conduction circuits 303, using the test loop 360, a test signal representing a differential electrical fault of a specific type, and to check that the detection of this specific electrical fault thus injected is indeed carried out, by means of the measurement loop 312, combined with the detection filter 322 and the microcontroller 320. The entire detection chain of the protection device 300 is thus checked, specifically for the differential fault type considered. This check is possible when no electrical load is connected to the protection device 300 considered.

Preferably, each first test signal is stored in the form of a digital test signal in the memory of the microcontroller 320, while the first test signal injected by the test loop 360 is an analogue signal. The microcontroller 320 thus comprises a digital-to-analogue converter 362, which is configured to transform each test signal in digital form into an analogue signal of the test loop. In the schematic example illustrated, the digital-to-analogue converter 362 is separate from the microcontroller 320 and is interposed between the microcontroller 320 and the test loop 360 and comprises a digital input, which is connected to an output of the microcontroller 320, and an analogue output, which is connected to the test loop 360. In a variant that is not shown, the digital-to-analogue converter 362 is integrated with the rest of the microcontroller 360, for example in the same integrated circuit or within the same electronic board.

Advantageously, the microcontroller 320 is configured to detect differential faults of several different types. A respective detection filter 322 corresponds to each differential fault type, the detection filter 322 associated with each differential fault type being previously stored in the memory of the microcontroller 320.

The communication means 354 of the protection device 300 are advantageously configured to receive configuration information from a device that is remote from the protection device, so as to specify the one or more types of differential faults for which, in the event that the corresponding differential fault is detected, the microcontroller sends the trip signal to the actuator. In other words, the microcontroller 320 is remotely configurable, the configuration information including the type of electrical fault against which the protection device 300 must protect. Thus, the configuration information is used to specify the particular detection filter 322 which must be implemented for the detection of a specific differential fault. Depending on the case, a plurality of detection filters 322 are previously stored in the memory of the microcontroller 320, and the configuration information specifies which of the detection filters 322 must be activated for the detection of the electrical faults. Alternatively, a single detection filter 322 is stored in the memory of the microcontroller 320, and the configuration information contains the new detection filter, which is stored in place of the previous detection filter.

Symmetrically, a specific test signal corresponds to each differential fault type. When a new detection filter 322 is specified by the configuration information, it is also necessary to specify a new test signal which corresponds to the same type of electrical fault as the new detection filter. For each differential fault type considered amongst the plurality of differential fault types, the microcontroller 320 is configured to inject, into the conduction paths 303, a corresponding test signal, which is an electrical signal representative of the electrical fault of the type considered.

Depending on the case, a plurality of test signals are previously stored, in digital form, in the memory of the microcontroller 320, and the configuration information specifies which of the test signals must be activated in order to check the correct operation of the detection chain, in particular check that the correct detection filter 322 is activated. Alternatively, a single test signal is stored in the memory of the microcontroller 320, and the configuration information contains the new test signal, which is stored in place of the previous test signal.

Thus, the protection device 300 as described above is configured to implement a test method which includes:
a step 611 of injecting, into the conduction paths 303 and using the test loop 360, a first test signal representative of a differential fault of a first predetermined type, characteristics of the differential fault of the first type being previously stored in a memory of the microcontroller,
during the injection of the first test signal, a step 612 of measuring, in the conduction paths 303 and using the measurement loop 312, a differential current between the conduction paths 303,
a step 613 of comparing the differential current measurement with a first detection filter 322 that is characteristic of the differential fault of the same type as the first test signal, the first detection filter being previously stored in a memory of the microcontroller 320, then
as a result of the comparison step 613, a step 614 of determining a differential fault corresponding to the differential fault type considered.

For example, if the result of the determination step 614 is positive, the microcontroller 320 sends, to the actuator 324, a trip signal for the cut-off means 310.

Advantageously, prior to injecting the first test signal into the conduction paths, the test method includes:
a step 610 of receiving configuration information, with the help of the transmission means 354, so as to specify a differential fault type amongst a plurality of differential fault types previously stored in the memory of the microcontroller, for which, in the event that the corresponding differential fault is detected, the microcontroller sends a trip signal to the cut-off means 310—here to the actuator 324.

Then, during the step 611 of injecting the first test signal into the conduction paths, the first test signal corresponds to the differential fault type previously specified by the configuration information during the step 610 of receiving configuration information.

During the step 613 of comparing the differential current measurement, the detection filter corresponds to the differential fault type previously specified by the configuration information during the step 610 of receiving configuration information.

Advantageously, the results of the test are transmitted to the user, for example the results are transmitted to the main housing 200, via the transfer bus 150. It is thus possible to individually test each of the protection devices 300 which are mounted on the distribution device 110.

The embodiments and the variants mentioned above may be combined with one another to create new embodiments of the invention.

1. An electrical protection device, configured to connect a power source to an electrical load, the protection device comprising:
at least two conduction paths, including a first path, which is configured to be connected to a phase of the power source, and a second path, which is configured to be connected either to another phase of the power source, or to a neutral of the power source, each conduction path comprising:
an incoming terminal, which is configured to be connected to a phase,
an outgoing terminal, which is associated with the incoming terminal and which is configured to be connected to a terminal of the electrical load, and
cut-off means, which are configured to switch between an armed configuration, in which each incoming terminal is electrically connected to the associated outgoing terminal, and a tripped configuration, in which each incoming terminal is electrically isolated from the associated outgoing terminal,
detection means, which include measurement loops configured to measure a current flowing through each conduction path,
a microcontroller, which is configured to:
evaluate the differential current measurement of the detection means with the help of a first detection filter, the first detection filter being previously stored in a memory of the microcontroller and being designed to detect a differential fault of a first type, and
when a differential fault of the first type is detected, send a trip signal to the cut-off means, so as to cause the cut-off means to switch from the armed configuration to the tripped configuration,
wherein:
the protection device comprises a test loop, which is different from the measurement loop and which is configured to inject an electrical signal into the conduction paths,
the microcontroller is configured:
to inject a first test signal into the conduction paths by means of the test loop, the first test signal being an electrical signal representative of the electrical fault of the first type and, at the same time,
to measure, by means of the measurement loop, the first test signal injected into the conduction paths by means of the test loop.

2. The electrical protection device according to claim 1, wherein:
the microcontroller comprises a digital-to-analogue converter, an analogue output of the digital-to-analogue converter being connected to the test loop,
each test signal is stored in the form of a digital test signal in the memory of the microcontroller,
each test signal in digital form is transformed, by the digital-to-analogue converter, into an analogue signal of the test loop, the analogue signal of the test loop being the first test signal.

3. The electrical protection device according to claim 1, wherein:
the microcontroller is configured to detect differential faults of a plurality of different types, the plurality of types including the first type,
a respective detection filter corresponds to each differential fault type, the detection filter associated with each differential fault type being previously stored in the memory of the microcontroller,
the protection device comprises communication means, which are configured to receive configuration information from a device that is remote from the protection device, so as to specify the one or more types of differential faults for which, in the event that the corresponding differential fault is detected, the microcontroller sends the trip signal to the cut-off means.

4. The electrical protection device according to claim 3, wherein:
the plurality of differential fault types include at least one differential fault type defined by the IEC 60755:2017 standard.

5. The electrical protection device according to claim 3, wherein:
a respective test signal corresponds to each differential fault type, the test signal associated with each differential fault type being previously stored in the memory of the microcontroller,
for each differential fault type considered amongst the plurality of differential fault types, the microcontroller is configured to inject, into the conduction paths, a corresponding test signal, the corresponding test signal being an electrical signal representative of the electrical fault of the type considered.

6. The electrical protection device according to claim 3, wherein:
the protection device comprises, in addition to the incoming and outgoing terminals, transfer terminals, which are intended to be connected to a transfer bus, so as to supply the microcontroller with electrical energy independently of the armed or tripped configuration of the switching mechanism.

7. The electrical protection device according to claim 6, wherein:
the communication means are configured to receive the configuration information via the transfer terminals and the transfer bus.

8. A distribution assembly, comprising:
a protection device configured to connect a power source to an electrical load, the protection device comprising:
at least two conduction paths, including a first path, which is configured to be connected to a phase of the power source, and a second path, which is configured to be connected either to another phase of the power source, or to a neutral of the power source, each conduction path comprising:
an incoming terminal, which is configured to be connected to a phase,
an outgoing terminal, which is associated with the incoming terminal and which is configured to be connected to a terminal of the electrical load, and
cut-off means, which are configured to switch between an armed configuration, in which each incoming terminal is electrically connected to the associated outgoing terminal, and a tripped configuration, in which each incoming terminal is electrically isolated from the associated outgoing terminal,
detection means, which include measurement loops configured to measure a current flowing through each conduction path, and a test loop, which is different from the measurement loop and which is configured to inject an electrical signal into the conduction paths, and
a distribution device with a power bus,
wherein:
the protection device is mounted on the distribution device in a reversible manner, the incoming terminals being electrically connected to the power bus.

9. (canceled)

10. A method of testing an electrical protection device, the protection device configured to connect a power source to an electrical load, the protection device comprising:
at least two conduction paths, including a first path, which is configured to be connected to a phase of the power source, and a second path, which is configured to be connected either to another phase of the power source, or to a neutral of the power source, each conduction path comprising:
an incoming terminal, which is configured to be connected to a phase,
an outgoing terminal, which is associated with the incoming terminal and which is configured to be connected to a terminal of the electrical load, and
cut-off means, which are configured to switch between an armed configuration, in which each incoming terminal is electrically connected to the associated outgoing terminal, and a tripped configuration, in which each incoming terminal is electrically isolated from the associated outgoing terminal,
detection means, which include measurement loops configured to measure a current flowing through each conduction path, and
a test loop, which is different from the measurement loop and which is configured to inject an electrical signal into the conduction paths,
the test method including:
injecting, into the conduction paths and using the test loop, a first test signal representative of a differential fault of a first predetermined type, characteristics of the differential fault of the first type being previously stored in a memory of the microcontroller,
during the injection of the first test signal, measuring in the conduction paths and using the measurement loop, a differential current between the conduction paths,
comparing the differential current measurement with a first detection filter that is characteristic of the differential fault of the same type as the first test signal, the first detection filter being previously stored in a memory of the microcontroller, then
as a result of the comparison, determining a differential fault corresponding to the differential fault type considered, then, if the result of the determination is positive, sending, via the microcontroller, a trip signal for the cut-off means.

11. The method according to claim 10, including:
prior to injecting the first test signal into the conduction paths, receiving configuration information, with the help of the transmission means, so as to specify a differential fault type amongst a plurality of differential fault types previously stored in the memory of the microcontroller, for which, in the event that the corresponding differential fault is detected, microcontroller of the protection device sends the trip signal to the cut-off means,
then, when the first test signal is being injected into the conduction paths, the first test signal corresponds to the differential fault type specified by the configuration information,
then, when the differential current measurement is being compared, the detection filter corresponds to the differential fault type specified.

12. The electrical protection device according to claim 1, wherein the incoming terminal is configured to be connected to the neutral of the power source.

13. The electrical protection device according to claim 1, further comprising an enclosure having a bottom, wherein the protection device is fixed to the bottom of the enclosure.

14. The distribution assembly according to claim 8, further comprising an enclosure having a bottom, wherein the distribution assembly is fixed to the bottom of the enclosure.
